(19) United States
(12) Patent Application Publication
(10) Pub. No.: US 2025/0096156 A1
(43) Pub. Date: Mar. 20, 2025

(54) PACKAGES WITH LOW-PROFILE POLYIMIDE LAYERS

(71) Applicant: TEXAS INSTRUMENTS INCORPORATED, Dallas, TX (US)

(72) Inventors: Katleen Fajardo TIMBOL, Allen, TX (US); Hung-Yun LIN, Murphy, TX (US); Xuan Mo LI, Chengdu (CN)

(21) Appl. No.: 18/470,321

(22) Filed: Sep. 19, 2023

(51) Int. Cl. H01L 23/00; H01L 21/027; H01L 21/304; H01L 21/56; H01L 23/31; H01L 23/498

(52) U.S. Cl. CPC H01L 23/562; H01L 21/0274; H01L 21/304; H01L 21/565; H01L 23/3171; H01L 23/49816; H01L 24/29; H01L 2224/29011; H01L 2224/29025; H01L 2924/35

(57) ABSTRACT

In examples, a package comprises a semiconductor die having a device side comprising circuitry formed therein. The package comprises a planarized passivation layer abutting the device side and a horizontal metal member coupled to the device side by way of vias extending through the passivation layer. The horizontal metal member has a thickness ranging between 4 microns and 25 microns. The package also comprises a metal post coupled to and vertically aligned with the horizontal metal member without a sputtered seed layer between the metal post and the horizontal metal member. The metal post has a vertical thickness ranging between 10 microns and 80 microns. The package also comprises a polyimide (PI) layer contacting the metal post, the horizontal metal member, and the passivation layer. The PI layer is not positioned between the metal post and the horizontal metal member. A thickness of a thickest portion of the PI layer ranges between 3 microns and 80 microns.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. Dies are then coupled to a lead frame and are covered by a mold compound, which is subsequently sawn to produce a package.

### SUMMARY

In examples, a package comprises a semiconductor die having a device side comprising circuitry formed therein. The package comprises a planarized passivation layer abutting the device side and a horizontal metal member coupled to the device side by way of vias extending through the passivation layer. The horizontal metal member has a thickness ranging between 4 microns and 25 microns. The package also comprises a metal post coupled to and vertically aligned with the horizontal metal member without a sputtered seed layer between the metal post and the horizontal metal member. The metal post has a vertical thickness ranging between 10 microns and 80 microns. The package also comprises a polyimide (PI) layer contacting the metal post, the horizontal metal member, and the passivation layer. The PI layer is not positioned between the metal post and the horizontal metal member. A thickness of a thickest portion of the PI layer ranges between 3 microns and 80 microns.

In examples, a method of manufacturing a package comprises providing a semiconductor die having a planarized passivation layer on the die and a horizontal metal member on the passivation layer, with the horizontal metal member coupled to the die through a via extending through the passivation layer, with the horizontal metal member having a thickness ranging between 4 microns and 25 microns, and with the vias having diameters ranging between 0.5 microns and 10 microns. The method also comprises plating a metal post directly on the horizontal metal member without applying a seed layer on the horizontal metal member. The method also comprises applying a polyimide (PI) layer to contact the horizontal metal member, the passivation layer, and the metal post. The method also includes using a mask to expose a portion of the PI layer. The method also includes developing the PI layer, thereby causing the PI layer to decrease in thickness along a circumference of the metal post and to form a peak at which a thickness of the PI layer is greatest, with the peak forming a ring surrounding the metal post and horizontally spaced from the metal post by a horizontal distance ranging between 0 micron and 30 microns.

### BRIEF DESCRIPTION OF THE DRAWINGS

FIG. 1 is a block diagram of an electronic device including a package having a low profile polyimide layer, in accordance with various examples.

FIG. 2A is a profile, cross-sectional view of a package having a low profile polyimide layer, in accordance with various examples.

FIG. 2B is a bottom-up view of a package having a low profile polyimide layer, in accordance with various examples.

FIG. 2C is a perspective view of a package having a low profile polyimide layer, in accordance with various examples.

FIG. 3 is a flow diagram of a method for manufacturing a package having a low profile polyimide layer, in accordance with various examples.

FIGS. 4A1-4G3 are a process flow of a method for manufacturing a package having a low profile polyimide layer, in accordance with various examples.

### DETAILED DESCRIPTION

Some packages include semiconductor dies that are coupled to metal (e.g., copper) posts through a network of metal and insulative layers, such as a redistribution layer (RDL). The copper posts may then be coupled to an external device, such as a printed circuit board (PCB), to facilitate communications with other devices that are also coupled to the PCB.

Generally, manufacturing such packages—and specifically, the RDL—entails iteratively sputtering seed layers for subsequent plating of metal layers. For example, a first seed layer may be sputtered to facilitate the plating of a metal layer in the RDL After this metal layer is plated, a polyimide (PI) layer may be applied to the metal layer and etched to form an opening in the PI layer above the metal layer. A second seed layer may then be sputtered in the opening of the PI layer to facilitate the plating of a metal post in the opening. This technique presents at least two technical disadvantages. First, the application of the PI layer prior to plating the metal post results in a limited contact area between the metal post and the underlying metal layer, resulting in diminished current density and flow properties. Second, multiple sputtering steps are required. These disadvantages present suboptimal performance, manufacturing speed, and manufacturing costs.

The disadvantages described above may be mitigated by forming the aforementioned metal layer in the RDL, plating the metal post directly on the metal layer without sputtering a second seed layer or applying a PI layer, and then, after the metal post has been formed, applying the PI layer. However, this approach also presents its own technical disadvantages. For example, applying the PI layer after the metal post has been plated on the metal layer results in a PI layer that will climb the outer surface of the metal post due to capillary action. The PI layer will approach the top surface of the metal post (i.e., the metal post surface most distal to the metal layer on which the metal post is plated). The top surface of the metal post is an area at which several different materials converge, such as the polyimide of the PI layer, the metal of the metal post, solder deposited on the metal post, mold compound covering the various components of the package, etc. The confluence of such disparate materials results in significant mechanical instability, resulting in the formation of cracks, for example. Such cracks can potentially render the package functionally useless. Applying a thinner PI layer does not solve this technical challenge, as a thinner PI layer can result in undesirable particle trapping.

This disclosure describes various examples of packages with low profile PI layers that mitigate the technical problems described above. In the packages described herein, the metal post is plated directly on the metal layer of the RDL prior to application of the PI layer. The PI layer is then applied after the metal post is formed. Consequently, the number of sputtering steps is reduced to one, and the entire bottom surface of the metal post most proximal to the metal layer makes direct contact with the metal layer. In this way, manufacturing is made more efficient and less expensive, and greater current densities are achieved at the junction between the metal post and the underlying metal layer on which the metal post is plated.

Further, after the PI layer is applied, a specific portion of the PI layer is thinned through photolithography techniques. In particular, the PI layer that is present within a target radius of the metal post is thinned using photolithography techniques so that the PI layer does not terminate at the top surface of the metal post. Rather, the PI layer has a low profile, such that the PI layer terminates approximately halfway up the height of the metal post (or lower). In this way, the number of disparate materials present at the top of the metal post is reduced by keeping the PI layer away from this area, and thus the mechanical instability described above is mitigated and crack formation is significantly reduced or eliminated. The precise thinning of the PI layer using photolithography techniques as described herein differs from depositing a globally thinner PI layer. The latter will be unacceptably thin and susceptible to particle trapping. In contrast, the former will produce an adequately thick PI layer that prevents particle trapping, while being adequately thinned in the strategic area surrounding the metal post so that the PI material is kept away from the top of the metal post, thus preventing the mechanical instability problems described above. Thus, the packages and related manufacturing techniques described herein provide numerous technical solutions to various technical problems. These packages and manufacturing techniques are now described with reference to the drawings.

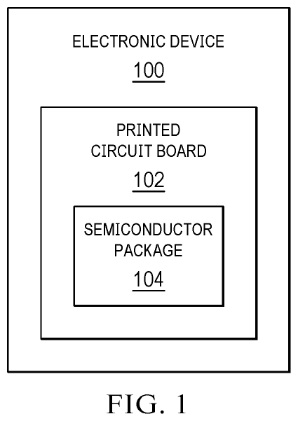

FIG. 1 is a block diagram of an electronic device including a package having a low profile polyimide layer, in accordance with various examples. Specifically, FIG. 1 shows a block diagram of an electronic device 100. The electronic device 100 may include, for example, a computing device (e.g., a laptop computer, a desktop computer, a notebook computer), a smartphone, a consumer electronic device (e.g., a television, a stereo system), an appliance, a vehicle (e.g., car or truck), an aircraft, a spacecraft, etc. The electronic device 100 may include a printed circuit board (PCB) 102 and a package 104 coupled to the PCB 102. The package 104 may have a low-profile PI layer as described herein, and the package 104 may be manufactured according to the various illustrative methods described herein.

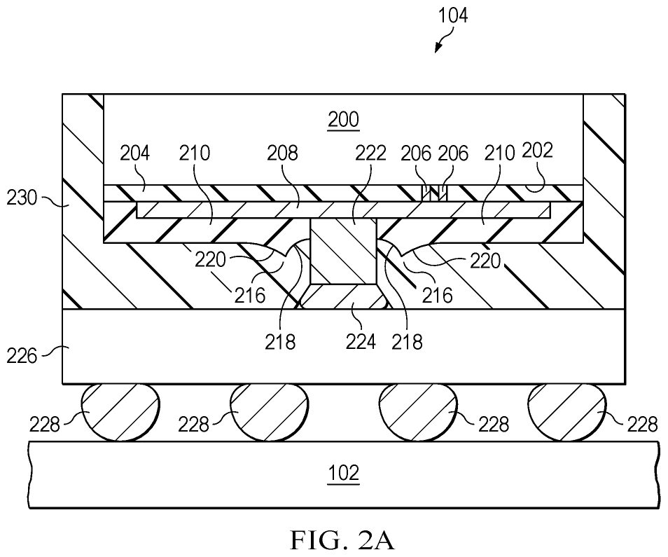

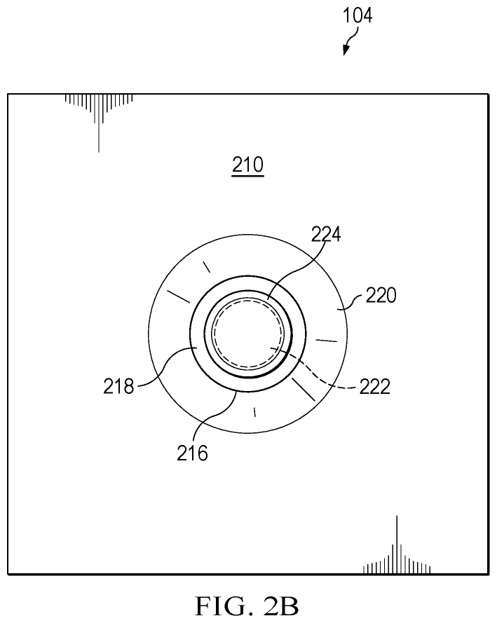

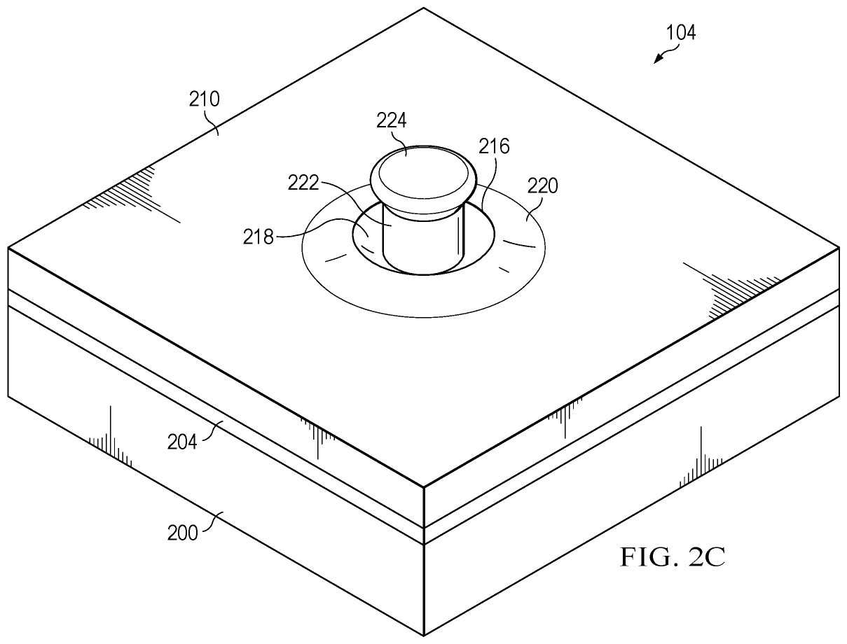

FIG. 2A is a profile, cross-sectional view of the package 104 having a low profile polyimide layer, in accordance with various examples. The package 104 includes a semiconductor die 200 (e.g., silicon, gallium nitride) having a device side 202 in and/or on which circuitry is formed. A passivation layer 204 contacts the device side 202 and vias 206 extend through the passivation layer 204. A metal layer 208 (e.g., a copper layer) contacts the passivation layer 204 and the vias 206. Thus, the vias 206 establish an electrical pathway between the circuitry on the device side 202 and the metal layer 208. A PI layer 210 contacts the passivation layer 204 and the metal layer 208. The PI layer 210 includes a peak 216 that forms a ring around a metal post 222 (e.g., a copper post). The peak 216 is the thickest point of the PI layer 210. The metal post 222 is vertically aligned with the metal layer 208, meaning that a common vertical line can extend through both the metal post 222 and the metal layer 208. In examples, slopes 218 and 220 descend from either side of the peak 216, with slope 218 contacting the metal post 222. In some examples, the slope 218 may be relatively flat (e.g., descending minimally or not at all), while the slope 220 descends downward. In the event the slope is completely flat, that portion of the PI layer 210 may still be referred to herein as a “slope” or “flat slope” for purposes of consistency in nomenclature. In the event the slope descends, the slope may be referred to as a “slope” or “downward slope.” The maximum thickness of the PI layer 210 is at the peak 216 and ranges from 3 microns to 80 microns measured from top surface of metal layer 208, with a thickness below this range being disadvantageous because a thinner PI layer 210 can result in undesirable particle trapping, and with a thickness above this range being disadvantageous because a thicker PI layer 210 can result in mechanical instability issues such as cracking in the PI layer 210 and delamination between the PI layer 210 and the passivation layer 204.

The distance from the outer wall of the metal post 222 to the peak 216 ranges from 0 micron to 30 microns. A distance between the outer wall of the metal post 222 and the peak 216 above this range is disadvantageous because the PI layer 210 can detach from the metal post 222 resulting in an incomplete fill of mold compound 230 within the gap between the PI layer 210 and the metal post 222.

Solder bumps 224 are coupled to top surfaces of the metal posts 222, as shown. A mold compound 230 covers the various structures of the package 104 described above. A layer 226 includes a network of metal layers and insulative layers that provide an electrical pathway between the solder bumps 224 and solder balls 228. The solder balls 228 are coupled to the PCB 102. Although the package 104 is depicted as a ball grid array (BGA) package, the package 104 may also have other physical forms, such as that of a quad flat no lead (QFN) package.

As shown, the point of contact between the PI layer 210 and the metal post 222 is located at or below (i.e., closer to the metal layer 208) the vertical midpoint of the metal post 222. For example, if the metal post has a total vertical height (i.e., thickness) of 40 microns, the contact point between the PI layer 210 and the metal post 222 would be located approximately 20 microns from the metal layer 208 or closer to the metal layer 208. in the vertical direction. By locating the contact point between the PI layer 210 and the metal post 222 within this range, the mechanical instability issues described above are mitigated.

Various structures within the package 104 have physical properties that facilitate high current densities and flows, which are useful, for instance, in high power applications. Such physical properties are critical to achieve target current densities and flows. Specifically, the metal layer 208 ranges from 4 microns to 25 microns. The metal post 222 ranges from 10 microns to 80 microns. The solder bump 224 has a thickness ranging from 10 microns to 60 microns, and the solder bump 224 has a composition consisting of an alloy of tin (between 80% and 100% of the total composition), silver (between 1% and 5% of the total composition), copper (between 0% and 5% of the total composition), and nickel (between 0% and 1% of the total composition). This solder composition is critical because the polyimide curing described below occurs significantly above the solder melting point. Under the passivation layer 204 (which may be a planarized passivation layer), the package 104 may include multiple back end of line (BEOL) metal layers composed of aluminum or copper, with a thickness in the range of 0.2 microns to 3 microns. The vias 206 have a diameter ranging from 0.5 microns to 10 microns. Physical dimensions of these structures in the package 104 below the aforementioned ranges are disadvantageous because it will result in unacceptable performance, and physical dimensions of these structures in the package 104 above the aforementioned ranges are disadvantageous because it will result in unacceptable manufacturing speed and manufacturing costs.

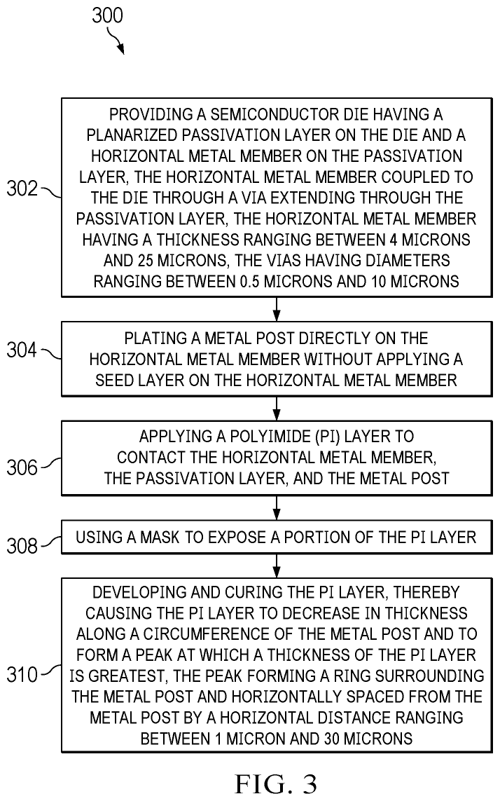

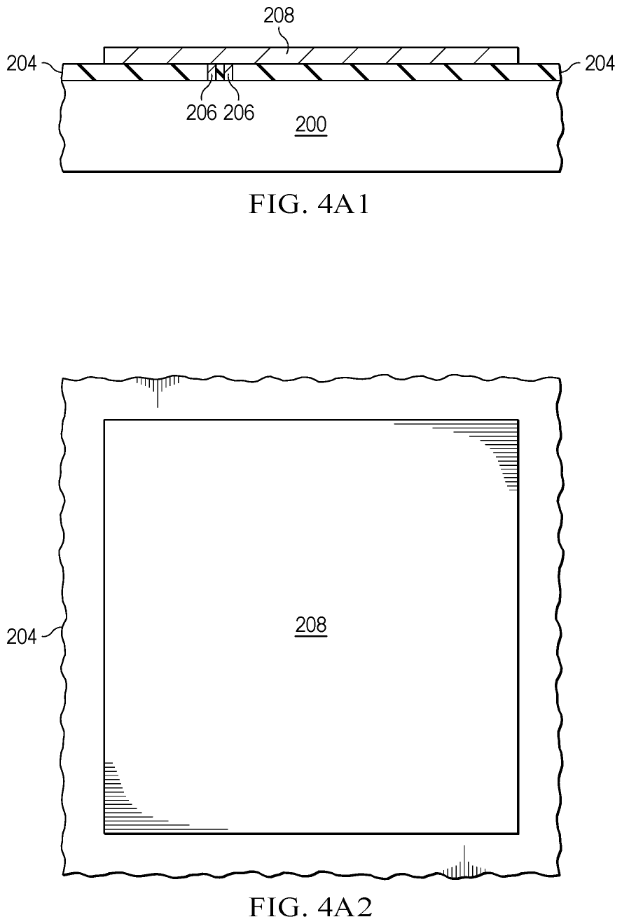

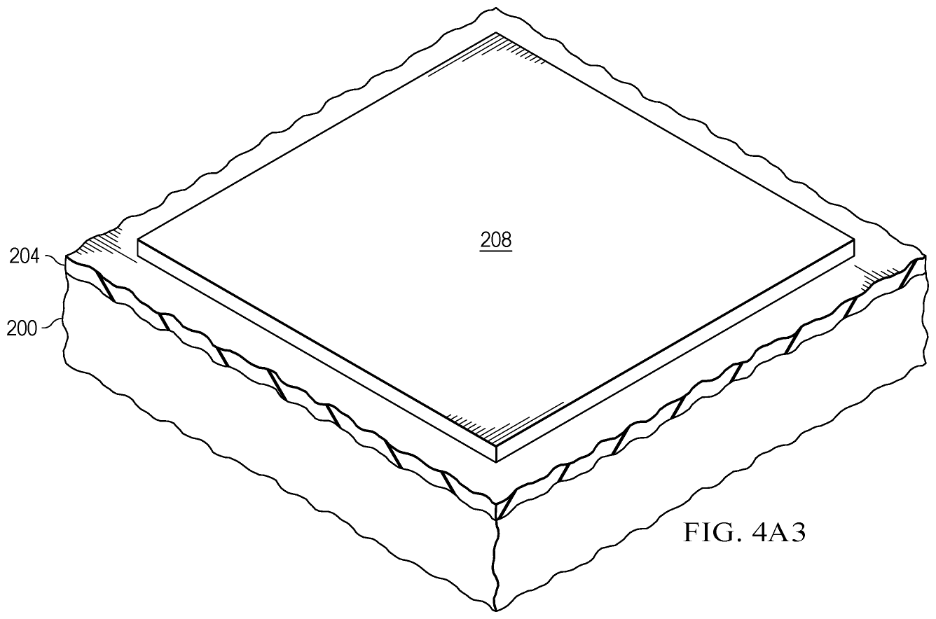

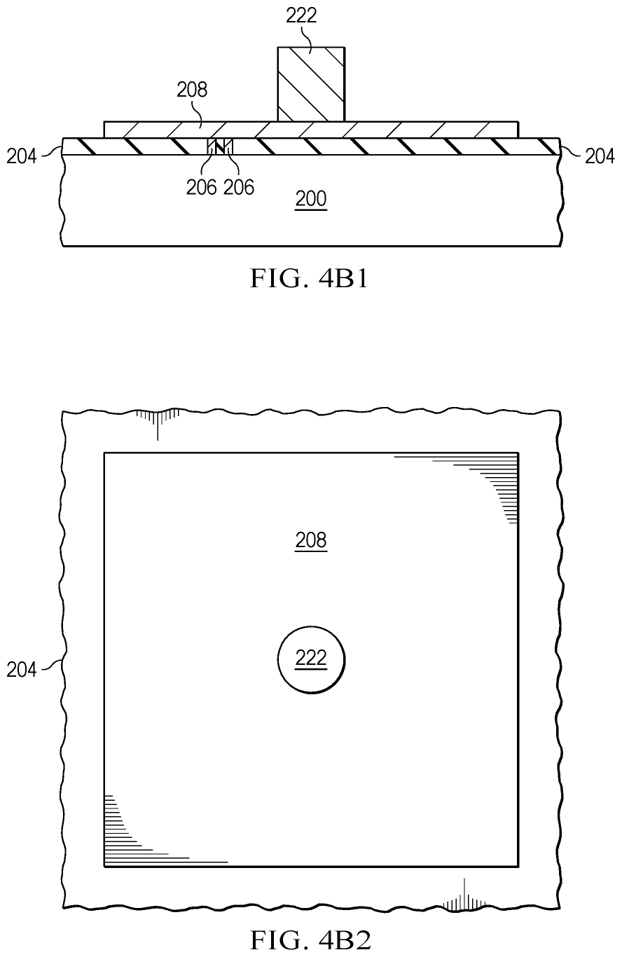

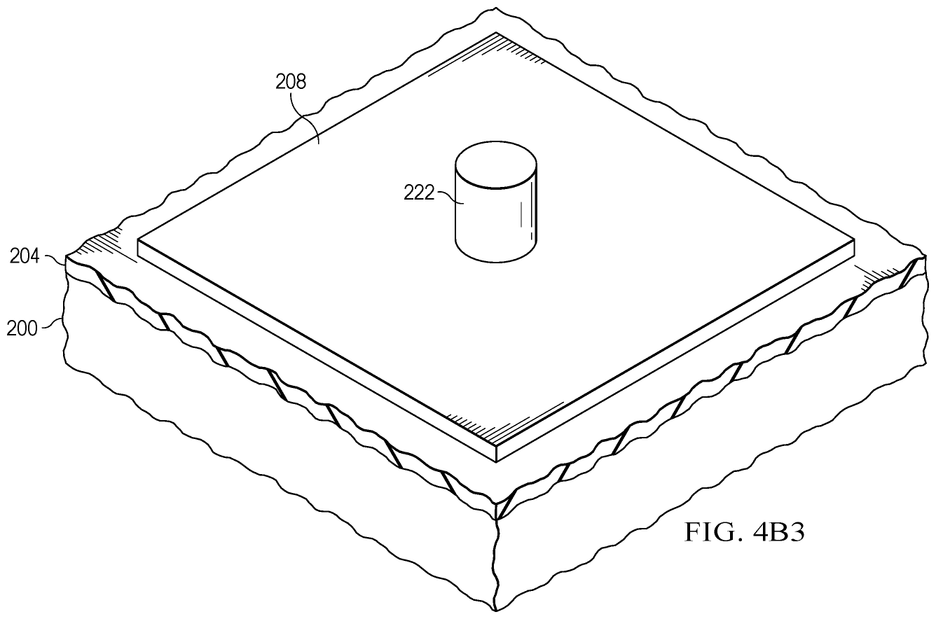

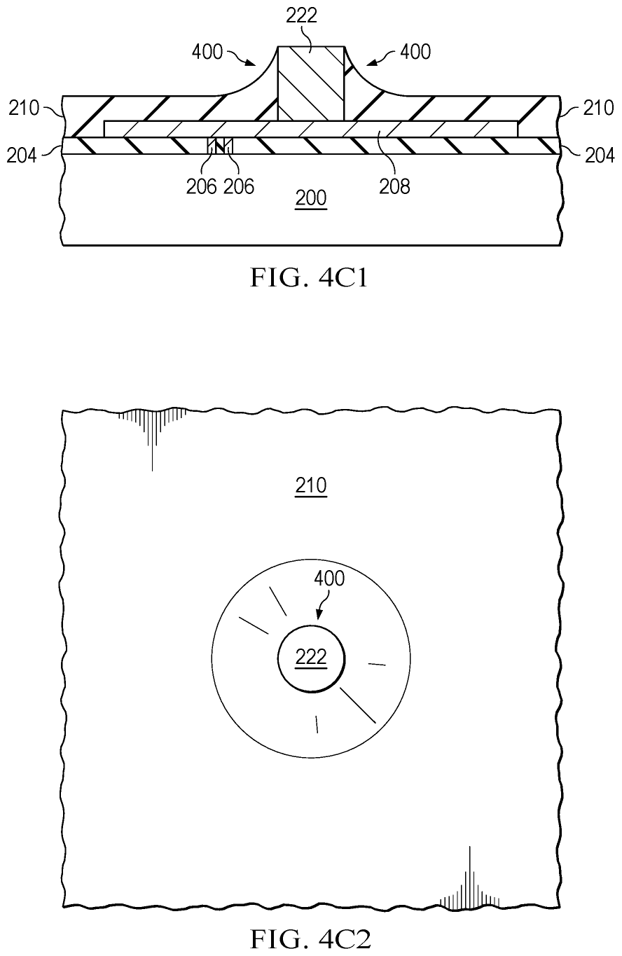

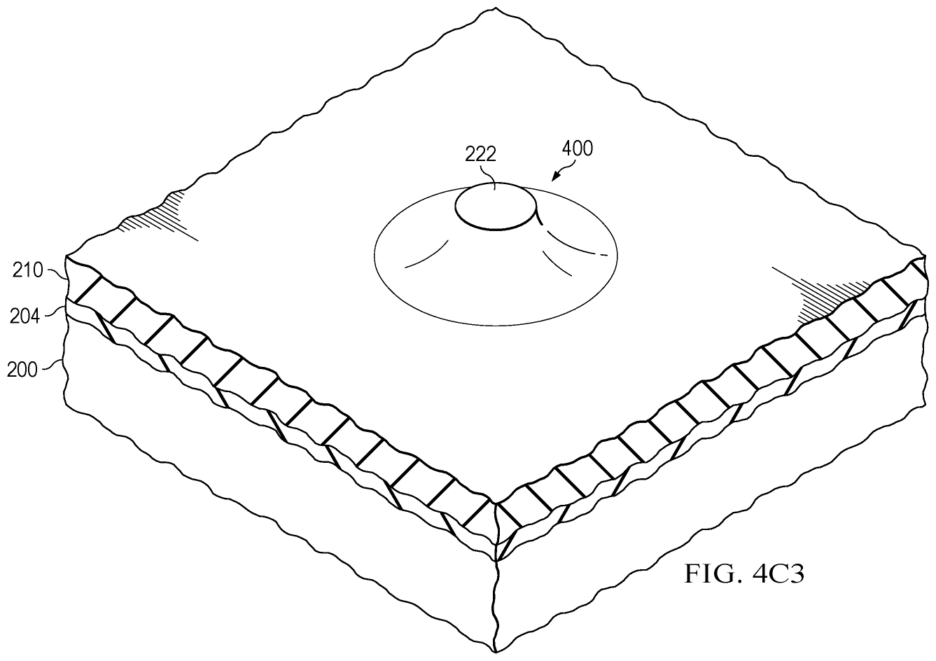

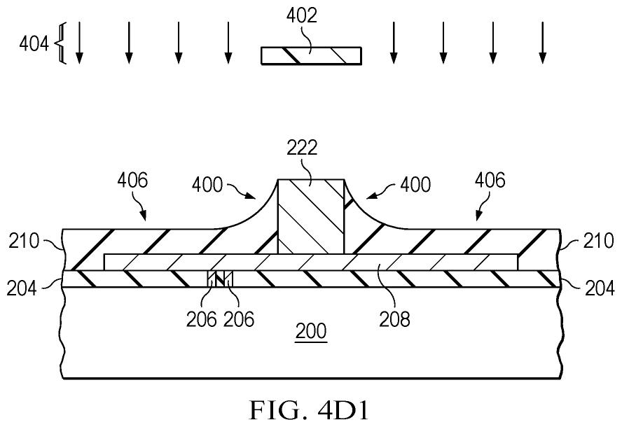

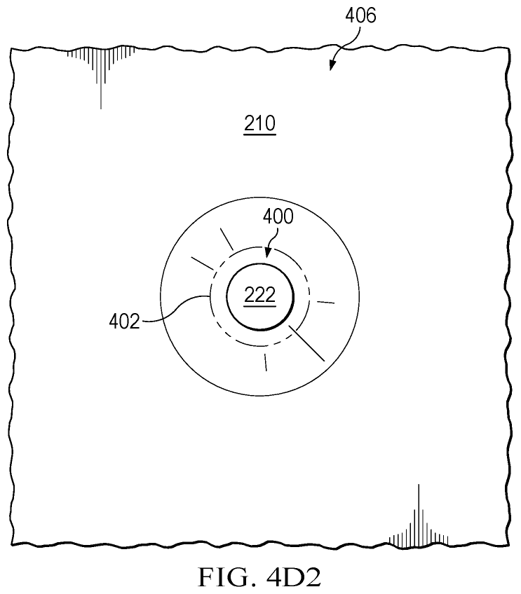

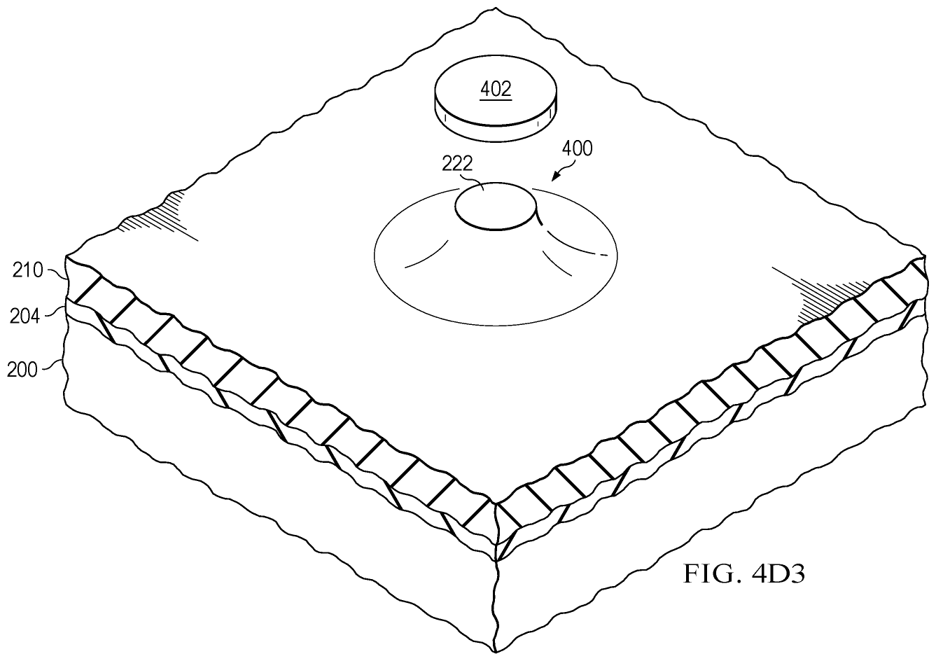

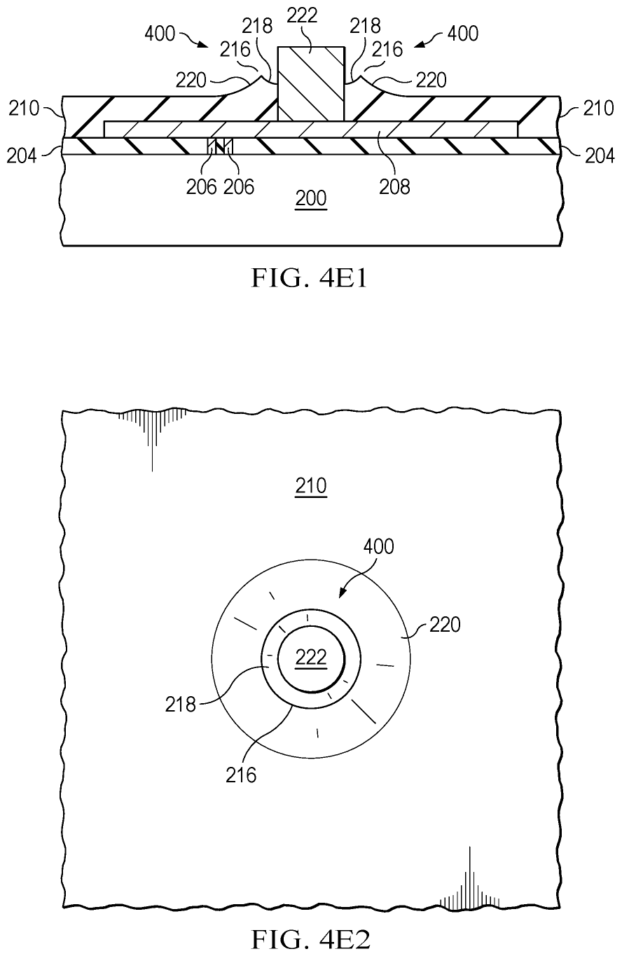

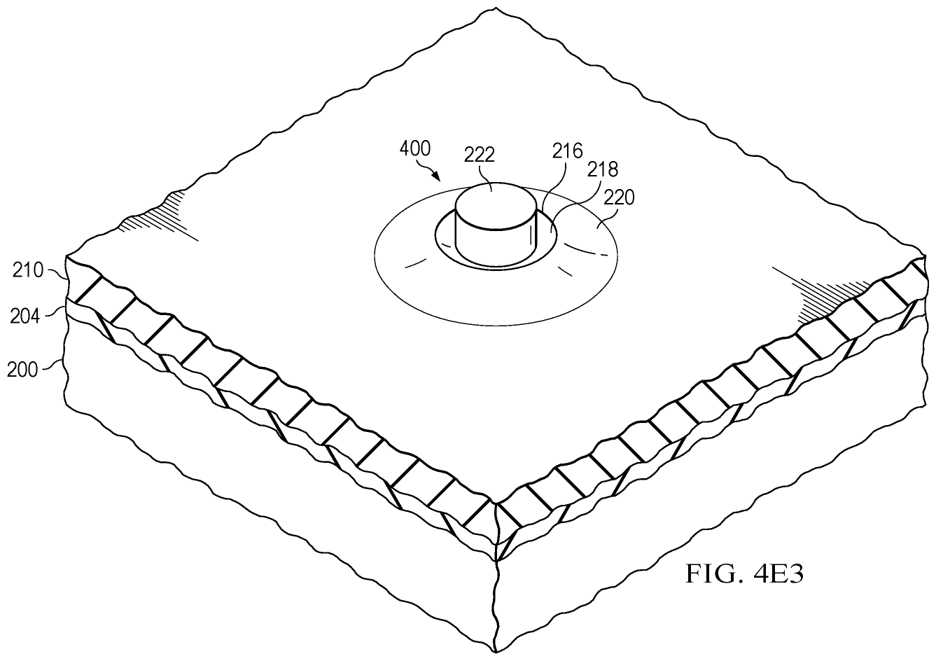

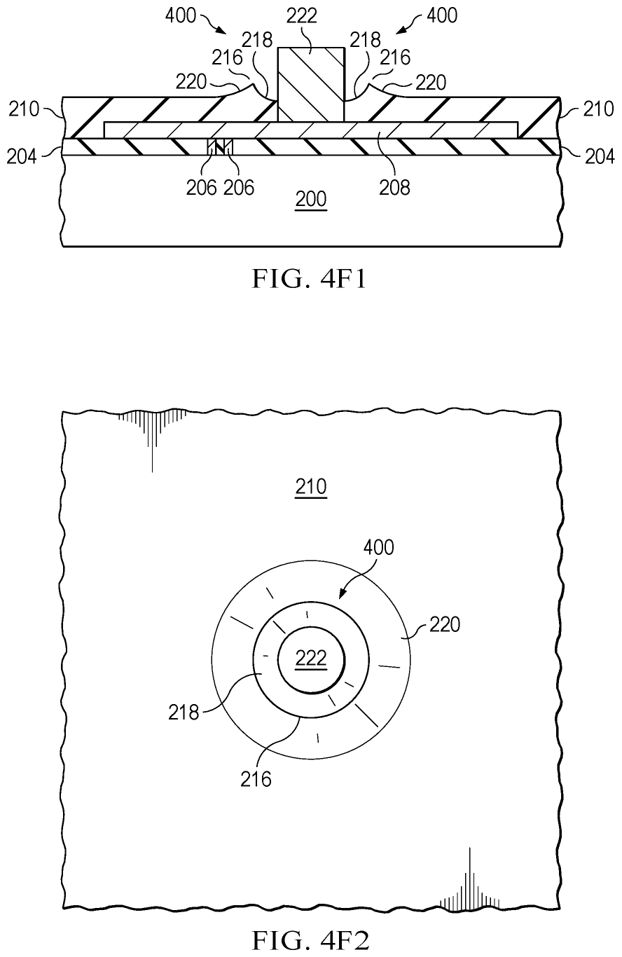

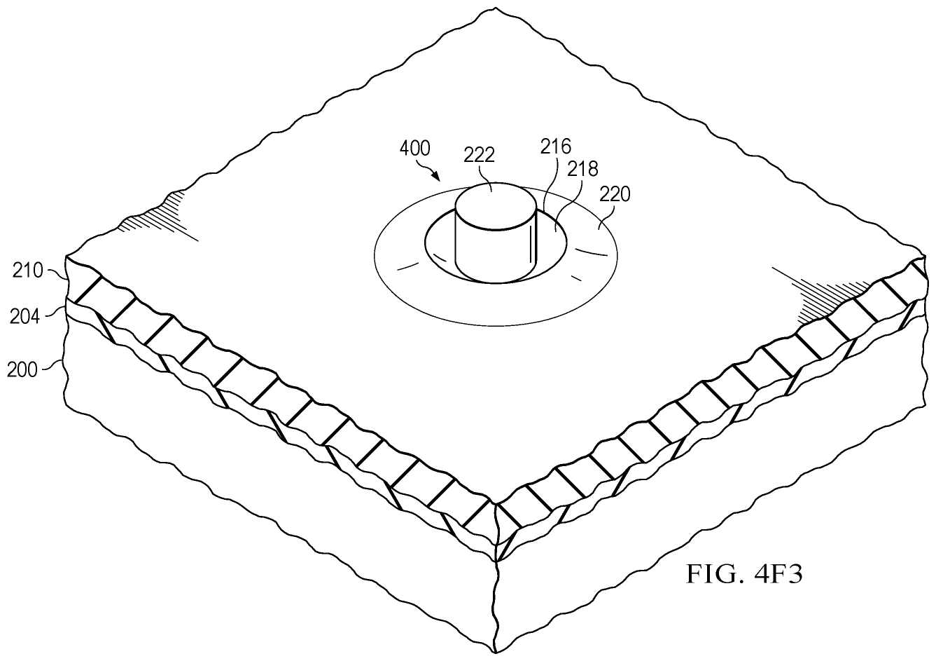

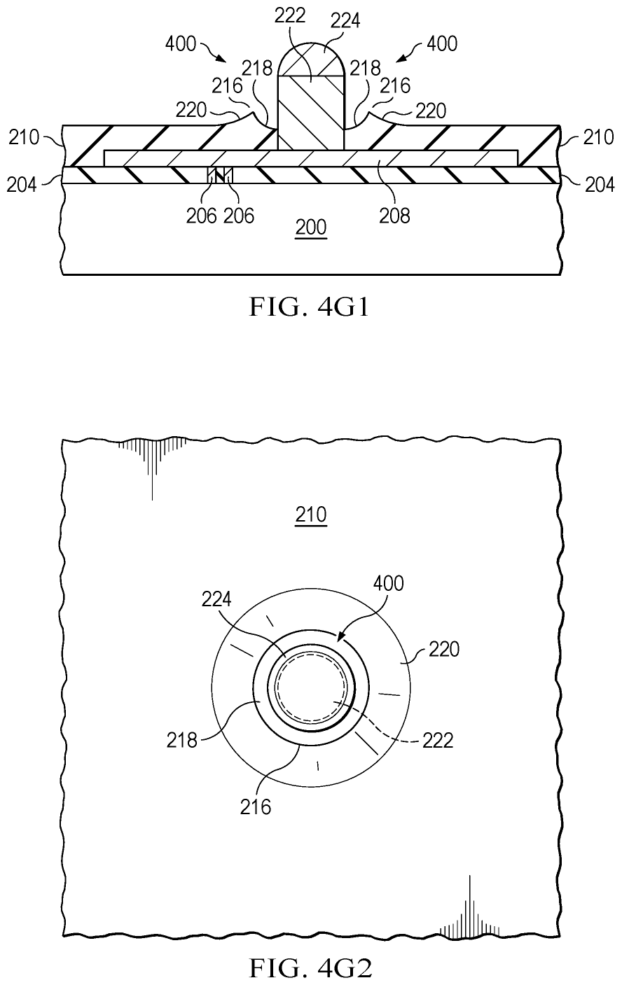

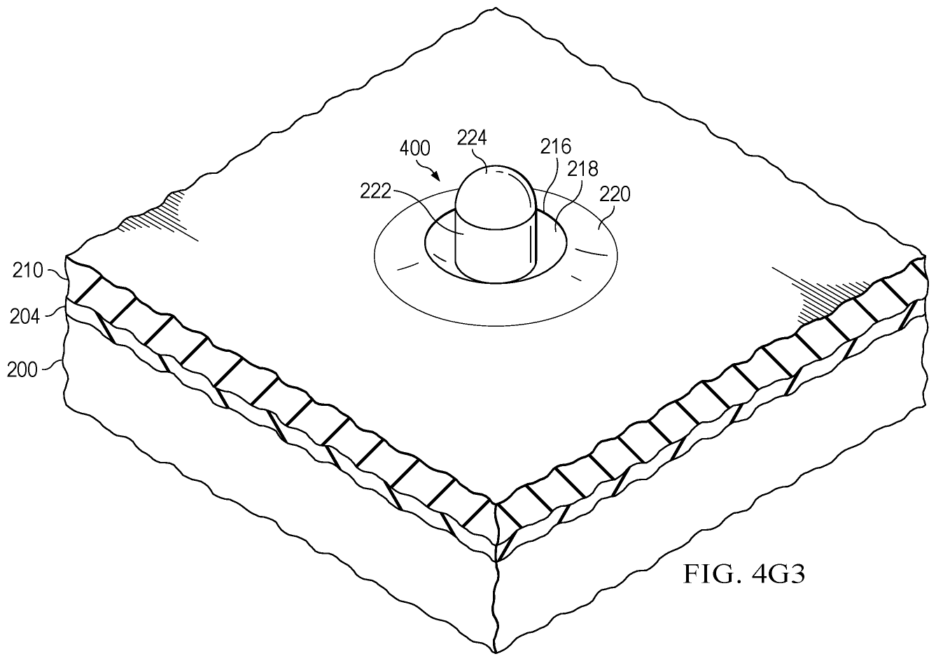

FIG. 3 is a flow diagram of a method 300 for manufacturing a package having a low profile polyimide layer, in accordance with various examples. The method 300 includes providing a semiconductor die, a planarized passivation layer on the die, and a horizontal metal layer on the passivation layer (302). The horizontal metal layer is coupled to the die through one or more vias extending through the passivation layer (302). The horizontal metal layer has a thickness ranging between 4 microns and 25 microns, as described above, and the vias have diameters ranging from 0.5 microns and 10 microns, as described above (302). FIG. 4A1 is a profile, cross-sectional view of the semiconductor die 200, the planarized passivation layer 204 contacting the die 200, and the metal layer 208 contacting the passivation layer 204. The vias 206 contact the device side of the die 200, extend through the passivation layer 204, and contact the metal layer 208. A seed layer (e.g., a copper seed layer) may be sputtered on the passivation layer 204, and the metal layer 208 may be plated using the sputtered seed layer. FIG. 4A2 is a top-down view of the structure of FIG. 4A1, in accordance with various examples. FIG. 4A3 is a perspective view of the structure of FIG. 4A1, in accordance with various examples.

The method 300 includes plating a metal post directly on the horizontal metal layer without sputtering a seed layer on the horizontal metal layer (304). A solder bump may also be deposited on the top surface of the metal post. FIG. 4B1 is a profile, cross-sectional view of the structure of FIG. 4A1, but with the addition of the metal post 222, which has been plated directly on the metal layer 208 without first sputtering another seed layer on the metal layer 208. This is possible because the PI layer has not yet been deposited, and thus the metal surface of the metal layer 208 is fully available for plating the metal post 222. Accordingly, the full bottom surface of the metal post 222 contacts the metal layer 208, as shown. The solder bump 224 is not yet deposited on the top surface of the metal post 222, because the PI layer must be deposited, shaped, and cured before application of the solder bump 224 as the PI curing temperature is so high that it would reflow the solder bump 224. FIG. 4B2 is a top-down view of the structure of FIG. 4B1, in accordance with various examples. FIG. 4B3 is a perspective view of the structure of FIG. 4B1, in accordance with various examples.

The method 300 includes applying a PI layer to contact the horizontal metal layer, the passivation layer, and the metal post (306). FIG. 4C1 is a profile, cross-sectional view of the structure of FIG. 4B1, but with the addition of the PI layer 210 on the metal layer 208, the passivation layer 204, and the metal post 222. A portion 400 of the PI layer 210 climbs the outer surface of the metal post 222 due to capillary action, as shown. The portion 400 encircles the metal post 222. The portion 400 may reach the top surface of the metal post 222, or the portion 400 may come close to the top surface of the metal post 222. FIG. 4C2 is a top-down view of the structure of FIG. 4C1, in accordance with various examples. FIG. 4C3 is a perspective view of the structure of FIG. 4C1, in accordance with various examples.

If mold compound and other structures are subsequently applied with the portion 400 remaining in place, the mechanical instability and functional integrity issues described above may occur. Thus, to mitigate the risk of these consequences, photolithography techniques may be useful to selectively reduce the height of the PI layer 210, and more specifically, to reduce the height of the portion 400. Accordingly, the method 300 includes using a mask to expose a portion of the PI layer (308). FIG. 4D1 is a profile, cross-sectional view of the structure of FIG. 4C1, but with the placement of a selectively patterned photo mask 402 above the PI layer 210. In examples, such as the example shown in FIG. 4C1, the PI layer 210 is a negative tone layer, meaning that the portions of the PI layer 210 to be removed or thinned by photolithography are protected from light 404 by the mask 402, while the portions of the PI layer 210 to be preserved are exposed to light 404 through the mask 402. In other examples, the PI layer 210 may be a positive tone layer, meaning that the portions of the PI layer 210 to be removed or thinned by photolithography are exposed to light 404 through the mask 402, while the portions of the PI layer 210 to be preserved are protected from light 404 by the mask 402. Because the PI layer 210 is a negative tone layer, the mask 402 protects the portion 400 from light 404, as the portion 400 is to be partially removed (i.e., thinned) so the portion 400 does not extend to or near the top surface of the metal post 222.

In the case of a negative tone PI layer 210, it is critical that the mask 402 extend horizontally at least 1 micron to 30 microns beyond the vertical plane in which the outer surface of the metal post 222 lies. Stated another way, in the setting of a negative tone PI layer 210, it is critical that the mask 402 have a radius that is between 1 micron and 30 microns larger than a radius of the metal post 222. In the case of a positive tone PI layer 210, it is critical that an opening in the mask 402 above the metal post 222 extend horizontally at least 1 micron to 30 microns beyond the vertical plane in which the outer surface of the metal post 222 lies. Stated another way, in the setting of a positive tone PI layer 210, it is critical that the mask 402 have an opening with a radius that is between 1 micron and 30 microns larger than a radius of the metal post 222. The range of 1 micron to 30 microns for both positive and negative tone PI layers is critical because, below this range, the PI layer 210 will approach the top surface of the metal post 222 and cause mechanical instability, and above this range, the PI layer 210 can detach from the metal post 222 resulting in incomplete fill of mold compound 230 within the gap between the PI layer 210 and the metal post 222.

As light 404 is applied, portions 406 of the PI layer 210 not covered by the mask 402 are exposed to the light 404. FIG. 4D2 is a top-down view of the structure of FIG. 4D1, in accordance with various examples. FIG. 4D3 is a perspective view of the structure of FIG. 4D1, in accordance with various examples.

The method 300 includes developing and curing the PI layer (310). The curing temperature is between 200 degrees Celsius and 380 degrees Celsius, with a curing temperature below this range being disadvantageous because it can result in incomplete polymerization and can outgas solvent at stressed conditions, and with a curing temperature above this range being disadvantageous because it can result in stiffer PI that impedes stress buffering performance. Developing and curing the PI layer causes the PI layer to decrease in thickness along a circumference of the metal post and to form a peak at which a thickness of the PI layer is greatest (310). The peak forms a ring surrounding the metal post and horizontally spaced from the metal post by a horizontal distance ranging between 0 microns and 30 microns (310). FIG. 4E1 is a profile, cross-sectional view of the structure of FIG. 4D1 after the PI layer 210 has been developed. As shown, the PI layer 210 has been selectively thinned at the portion 400, which terminates at approximately the midpoint of the thickness of the metal post 222. FIG. 4E2 is a top-down view of the structure of FIG. 4E1, in accordance with various examples. FIG. 4E3 is a perspective view of the structure of FIG. 4E1, in accordance with various examples. FIG. 4F1 is a profile, cross-sectional view of the structure of FIG. 4E1, except that the PI layer 210 has been cured, resulting in a more prominent peak 216, as shown. In addition, curing may further thin the portion 400, as also shown. FIG. 4F2 is a top-down view of the structure of FIG. 4F1, in accordance with various examples. FIG. 4F3 is a perspective view of the structure of FIG. 4F2, in accordance with various examples.

The solder bump 224 may be deposited on the metal post 222 after the PI layer 210 has been deposited, exposed, developed, and cured. FIG. 4G1 shows the structure of FIG. 4F1, but with the addition of the solder bump 224 on the metal post 222, in accordance with various examples. FIG. 4G2 is a top-down view of the structure of FIG. 4G1, in accordance with various examples. FIG. 4G3 is a perspective view of the structure of FIG. 4G1, in accordance with various examples.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A package, comprising:
a semiconductor die having a device side comprising circuitry formed therein;
a planarized passivation layer abutting the device side;
a horizontal metal member coupled to the device side by way of vias extending through the passivation layer, the horizontal metal member having a thickness ranging between 4 microns and 25 microns;
a metal post coupled to and vertically aligned with the horizontal metal member without a sputtered seed layer between the metal post and the horizontal metal member, the metal post having a vertical thickness ranging between 10 microns and 80 microns; and
a polyimide (PI) layer contacting the metal post, the horizontal metal member, and the passivation layer, wherein the PI layer is not positioned between the metal post and the horizontal metal member, and wherein a thickness of a thickest portion of the PI layer ranges between 3 microns and 80 microns.

2. The package of claim 1, wherein a thickest point of the PI layer forms a ring surrounding the metal post that is horizontally spaced from the metal post by a horizontal distance ranging between 0 microns and 30 microns.

3. The package of claim 1, wherein the PI layer is subjected to a photolithography process to produce a top surface that includes a peak at a thickest point of the PI layer, a first flat or downward slope between the peak and the metal post, and a second downward slope extending from the peak away and from the metal post.

4. The package of claim 1, wherein all of a bottom surface of the metal post contacts the horizontal metal member.

5. The package of claim 1, wherein the vias have diameters ranging between 0.5 microns and 10 microns.

6. A package, comprising:
a semiconductor die having a device side comprising circuitry and a formed therein;
a planarized passivation layer abutting the device side;
a horizontal metal member coupled to the device side by way of vias extending through the passivation layer, the horizontal metal member having a thickness ranging between 4 microns and 25 microns;
a metal post coupled to and vertically aligned with the horizontal metal member without a sputtered seed layer between the metal post and the horizontal metal member, the metal post having a vertical thickness ranging between 10 microns and 80 microns; and
a polyimide (PI) layer contacting the metal post, the horizontal metal member, and the passivation layer, wherein a thickest point of the PI layer forms a ring surrounding the metal post that is horizontally spaced from the metal post by a horizontal distance ranging between 0 micron and 30 microns.

7. The package of claim 6, wherein a thickness point of the PI layer has a thickness ranging between 3 microns and 80 microns.

8. The package of claim 6, wherein the PI layer is subjected to a photolithography process to produce a top surface that includes a peak at a thickest point of the PI layer, a first flat or downward slope between the peak and the metal post, and a second downward slope extending from the peak away and from the metal post.

9. The package of claim 6, wherein all of a bottom surface of the metal post contacts the horizontal metal member.

10. The package of claim 6, wherein the vias have diameters ranging between 0.5 microns and 10 microns.

11. A package, comprising:
a semiconductor die having a device side comprising circuitry and a formed therein;
a planarized passivation layer abutting the device side;
a horizontal metal member coupled to the device side by way of vias extending through the passivation layer, the horizontal metal member having a thickness ranging between 4 microns and 25 microns, the vias having diameters ranging between 0.5 microns and 10 microns;
a metal post coupled to and vertically aligned with the horizontal metal member without a sputtered seed layer between the metal post and the horizontal metal member, the metal post having a vertical thickness ranging between 10 microns and 80 microns; and
a polyimide (PI) layer contacting the metal post, the horizontal metal member, and the passivation layer, wherein the PI layer is not positioned between the metal post and the horizontal metal member, and wherein the PI layer is subjected to a photolithography process to produce a top surface that includes a peak at a thickest point of the PI layer and a downward slope extending from the peak in a direction away from the metal post.

12. The package of claim 11, wherein a thickness of the PI layer at the peak ranges between 3 microns and 80 microns.

13. The package of claim 11, wherein a thickest point of the PI layer forms a ring surrounding the metal post that is horizontally spaced from the metal post by a horizontal distance ranging between 0 micron and 30 microns.

14. The package of claim 11, wherein all of a bottom surface of the metal post contacts the horizontal metal member.

15. The package of claim 11, wherein the vias have diameters ranging between 0.5 microns and 10 microns.

16. A method of manufacturing a package, comprising:
providing a semiconductor die having a planarized passivation layer on the die and a horizontal metal member on the passivation layer, the horizontal metal member coupled to the die through a via extending through the passivation layer, the horizontal metal member having a thickness ranging between 4 microns and 25 microns, the vias having diameters ranging between 0.5 microns and 10 microns;
plating a metal post directly on the horizontal metal member without applying a seed layer on the horizontal metal member;
applying a polyimide (PI) layer to contact the horizontal metal member, the passivation layer, and the metal post;
using a mask to expose a portion of the PI layer; and
developing the PI layer, thereby causing the PI layer to decrease in thickness along a circumference of the metal post and to form a peak at which a thickness of the PI layer is greatest, the peak forming a ring surrounding the metal post and horizontally spaced from the metal post by a horizontal distance ranging between 0 micron and 30 microns.

17. The method of claim 16, wherein a thickness of the PI layer at the peak ranges between 3 microns and 80 microns.

18. The method of claim 16, wherein the PI layer includes a first flat or downward slope between the peak and the metal post, and a second downward slope extending from the peak away and from the metal post.

19. The method of claim 16, wherein all of a bottom surface of the metal post contacts the horizontal metal member.

20. The method of claim 16, further comprising applying the PI layer after the metal post is plated.

21. The method of claim 16, wherein the method includes a single seed layer sputtering step.
